(19) United States
(12) Patent Application Publication
(10) Pub. No.: US 2026/0181767 A1
(43) Pub. Date: Jun. 25, 2026

(54) PRINTED CIRCUIT BOARD WITH HEALABLE FEATURES

(71) Applicant: Sandisk Technologies, Inc., Milpitas, CA (US)

(72) Inventors: Ching Yoong Ang, Bukit Mertajam (MY); Chuan Yuan Chow, Batu Kawan (MY); Zong Zhe Hoo, Batu Kawan (MY); Sze Min Wong, Gelugor (MY); Muhammad Izzad Azhan Nordin, Nibong Tebal (MY)

(21) Appl. No.: 18/990,220

(22) Filed: Dec. 20, 2024

(51) Int. Cl. H05K 1/02; H05K 1/09

(52) U.S. Cl. CPC H05K 1/0292; H05K 1/092; H05K 2201/0154; H05K 2201/0391

(57) ABSTRACT

A printed circuit board (PCB) for an electronic device assembly, such as a solid state drive (SSD), includes at least one solder mask formed from a healable dielectric material and/or conductive traces formed from a healable conductive material. Thus, the solder mask(s) and/or conductive traces may be selectively healed. The healable dielectric material may flow when heated to a repair temperature. The healable conductive material may flow upon application of a repair voltage to it. Electronic device assemblies are also disclosed, as are methods for repairing solder masks and conductive traces of the PCBs of electronic device assemblies.

### BACKGROUND

A printed circuit board (PCB) of a data storage device typically includes a solder mask on each major surface of the PCB. The solder mask facilitates electrical coupling of a memory device (e.g., a NAND device), a controller, and other devices to the circuit board. Conventional solder masks, while effective initially, are prone to physical damage (e.g., scratches, cracks, etc.) that can compromise electronic connections between the circuit board and the memory device. Any physical damage degrades performance of the memory device, reduces the potential life span of the memory device and ultimately, lead to its failure.

PCBs also include conductive traces that convey electrical signals between devices mounted on the PCBs or otherwise electrically coupled to the PCBs. The conductive traces of PCBs are typically formed from copper, which has low resistivity and high conductivity. Over time and with repeated use, copper conductive traces may become damaged, affecting the performance and reliability of the PCB and of an electronic device that includes the PCB and may result in data errors, communication failures, and device malfunctions.

Accordingly, it would be beneficial for a PCB to include solder masks and/or conductive traces that can be healed. Further, it would be beneficial to have a PCB with solder masks and/or conductive traces that can be healed quickly and cost-effectively.

### SUMMARY

A printed circuit board (PCB) of this disclosure includes features that may heal when damaged. Such a PCB may be designed for use with one or more memory devices (e.g., one or more NAND devices, etc.) and/or as part of a solid-state drive (SSD). In some examples, the feature of the PCB that may heal may have a configuration that enables it to be selectively healed, or repaired. In other examples, the PCB may be part of an electronic device (e.g., an SSD, etc.) that may be programmed to heal the feature.

In some examples, the PCB may include a solder mask that, when damaged, may be selectively healed. The solder mask may comprise a dielectric material that may heal when exposed to a sufficient temperature. The dielectric material may be referred to as a “healable dielectric material.” The temperature that enables the healable dielectric material to heal may be referred to as a “repair temperature.” The healable dielectric material may comprise one or more dynamic covalent polymers (DCPs), Diels-Alder (DA) adducts, and/or metal-ligand coordination polymers (e.g., a zinc-ligan coordination polymer, etc.). In some examples, the healable dielectric material may comprise at least one dynamic covalent polymer, at least one DA adduct, and at least one metal-ligand coordination polymer.

The repair temperature of such a healable dielectric material may be about the same as an operating temperature of the electronic device of which the PCB is a part or greater, while being low enough to prevent thermal damage to the PCB and/or other devices and features of an electronic device assembly of which the PCB is a part. As an example, the repair temperature may be less than a reflow temperature of solder of an electronic device assembly of which the PCB is a part. The healable dielectric material may have a repair temperature of about 100° C. or more and about 180° C. or less. In some examples, the repair temperature of the healable dielectric material may be in a range of about 100° C. to about 150° C. or a range of about 100° C. to about 130° C.

A method for repairing damage to a solder mask of such a PCB may optionally include detecting damage to the solder mask. The method may also include applying heat to the damage and then allowing the material of the solder mask to cool. The heat may be applied specifically to a damaged area of the solder mask. Alternatively, the heat may be applied generally to an entirety of the solder mask, as well as to the PCB and to an electronic device assembly of which the PCB is a part (e.g., an SSD, etc.). The solder mask may be heated to a repair temperature that may enable the material of the solder mask to heal without damaging the PCB that carries the solder mask or any other components or features of an electronic device assembly of which the PCB and solder mask are a part. For example, the solder mask may be heated to a temperature in a range of about 100° C. to about 130° C., a range of about 100° C. to about 150° C., a temperature of up about 180° C., etc.

As heat is applied to the solder mask, hydrogen bonds in the healable dielectric material of the solder mask may break, covalent bonds of a DCP of the healable dielectric material of the solder mask may break, bonds formed by DA reactions in the healable dielectric material of the solder mask may break, and/or metal-ligand bonds in the healable dielectric material of the solder mask may dissociate. As the healable dielectric material of the solder mask cools, the hydrogen bonds in the healable dielectric material of the solder mask may be reestablished, the bonds that are formed in the healable dielectric material of the solder mask by DA reactions may be reestablished, and/or metal-ligand bonds in the healable dielectric material of the solder mask may reassociate, which may heal the damage to the solder mask.

In some examples, the PCB may include conductive traces, which may be referred to more simply as “traces,” that, when broken or otherwise damaged, may be selectively healed or automatically healed. The conductive traces of such a PCB may comprise a polyimide along with enough silver nanoparticles and copper nanoparticles dispersed throughout the polyimide to enable the trace to convey an electrical signal at an operating voltage (e.g., about 3.3 V to about 5 V, etc.) of an electronic device (e.g., an SSD, etc.) of which the PCB is a part. When such a trace is broken or otherwise damaged, it may be repaired by exposure to a repair voltage (e.g., about 5 V to about 10 V, etc.) that exceeds the operating voltage. Thus, such a material may be referred to as a “healable conductive material.”

The PCB may be part of an electronic device assembly (e.g., an SSD, etc.) that includes two or more semiconductor devices, such as a memory device (e.g., a NAND device, etc.) and a controller that communicate with each other by way of traces of the PCB. Each of the semiconductor devices may apply the repair voltage to a damaged trace. Where one of the semiconductor devices is a memory device, the memory device may include a multiplier circuit that increases the operating voltage to a repair voltage and selectively applies the repair voltage to a damaged trace.

A method for repairing a break in a trace or other damage to a trace of a PCB may include identifying each trace with a break or other damage and applying a repair voltage to the trace to repair the break. The repair voltage (e.g., about 5 V to about 10 V, etc.) may exceed an operating voltage (e.g., about 3.3 V to about 5 V, etc.) of the electronic device of which the PCB is a part. As the repair voltage is applied to the broken or otherwise damaged trace, the healable conductive material may heal the break or other damage. More specifically, the polymer and the silver nanoparticles and copper nanoparticles of the healable conductive material may flow across the break or other damage. Application of the repair voltage to opposite sides of the break or other damage (e.g., from both ends of the trace, etc.) may ensure that the repair is properly routed across the break or other damage. For example, the repair voltage may be applied from one side by a controller of the electronic device assembly. In examples where the repair voltage may be applied to opposite sides of the break or other damage, the repair voltage may be applied from the other side of the trace by a multiplier circuit of a memory device (e.g., a NAND device, etc.) of the electronic device assembly.

Other aspects of the disclosed subject matter, as well as features and advantages of various aspects of the disclosed subject matter, should be apparent to those of ordinary skill in the art through consideration of the ensuing description, the accompanying drawings, and the appended claims.

### BRIEF DESCRIPTION OF THE DRAWINGS

In the drawings:

FIG. 1 schematically depicts a healable solder mask on a printed circuit board (PCB);

FIGS. 2 through 5 schematically depict a process for repairing damage to the healable solder mask of FIG. 1;

FIG. 6 through 10 schematically depict an electronic device assembly with a PCB that includes healable traces;

FIG. 6 shows the PCB prior to breakage or other damage to any of its traces;

FIG. 7 depicts the PCB with traces that have broken or that have otherwise been damaged;

FIG. 8 illustrates the application of a repair voltage to a broken or otherwise damaged trace from opposite sides of the break or other damage;

FIG. 9 illustrates the application of a repair voltage to another broken or otherwise damaged trace from opposite sides of the break or other damage; and

FIG. 10 depicts the PCB with repaired traces.

### DETAILED DESCRIPTION

In SSD manufacturing and assembly, solder mask damage can have significant economic impacts. Yield losses from solder mask damage typically range from 2% to 5% of manufactured SSDs. Conventional repairs are costly and time consuming. However, there may be situations in which a solder mask of an SSD is damaged too severely to be repaired by conventional techniques may have to be scrapped. Thus, the total annual losses from repairing and scrapping SSDs with failed solder masks can be significant. The substantial financial impact underscores the need for improved solutions to effectively address solder mask damage.

Traditional methods to improve solder mask durability have included increasing the thickness of the coating or applying additional protective layers. While effective to some extent, these methods can lead to higher manufacturing costs and add complexity to manufacturing processes without addressing minor damage repair. Other approaches for improving SSD yields include manual repair techniques and frequent inspections, both of which are labor-intensive and, thus, are not cost-effective.

In addition to creating problems during the assembly of SSDs, solder mask damage may also be problematic over time, as a solder mask helps protect the PCB, the memory device(s) carried by the PCB, and the electrical connections between the memory device(s) and the PCB. Damage to the solder mask may compromise the integrity of the SSD, allow contaminants to come into contact with delicate components and features of the SSD, and allow for interference with the communication of electrical signals that are needed for the SSD to function properly.

The ability of an SSD to function reliably over long periods of time is also dependent upon the integrity of the conductive pathways of the SSD, including the conductive traces of the PCB of the SSD. The conductive traces, which are typically formed from copper, may degrade over time due to a variety of factors, including physical stress, thermal cycling, and electrical overstress. These and other factors can lead to broken or disconnected conductive traces, resulting in data errors, communication failures, and device malfunctions.

Conventional solutions for repairing broken conductive traces, such as manual intervention by re-soldering or using conductive adhesives, are not feasible in highly integrated systems with complex micro-scale circuits. Additionally, multiple broken traces close together pose a risk of accidental short-circuits or misconnections when repaired manually, leading to device failure. While some systems include redundant pathways to mitigate single-point failure, the use of redundant pathways adds to design complexity and necessitates increasing the size of the PCB of the SSD.

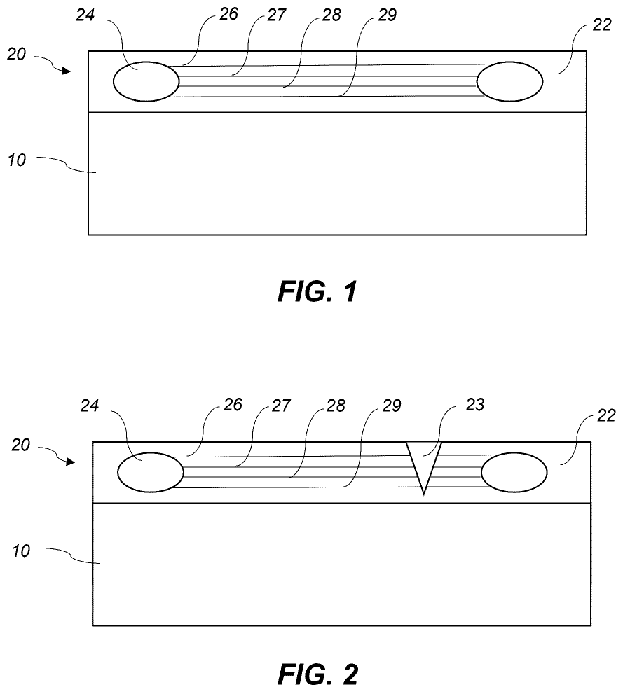

With reference to FIG. 1, an example of a printed circuit board (PCB) 10 is depicted. The PCB 10 includes a surface 12 that carries a solder mask 20. The solder mask 20 comprises a material that may be healed, or a healable dielectric material 22. Thus, the solder mask 20 comprises a healable solder mask. The healable dielectric material 22 of the solder mask 20 may facilitate the repair of damage to the solder mask 20 (e.g., scratches on the solder mask 20, microcracks or cracks in the solder mask 20, etc.).

The healable dielectric material 22 may include bonds that may be broken when heated and reestablished upon cooling. More specifically, the healable dielectric material 22 may comprise a base resin, one or more thermoplastic polymers, and at least one heat-activated reversible polymer (HARP) 24, The HARP 24 may comprise at least one dynamic covalent polymer (DCP), at least one Diels-Alder (DA) adduct, and/or at least one metal-ligand coordination polymer (e.g., a zinc-ligand coordination polymer, etc.).

The base resin of the healable dielectric material 22 may comprise a material that is durable, is electrically insulative, resists moisture, withstands high temperatures, and resists etching by solder flux. Examples of material suitable for use as the base resin as a solder mask include, but are not limited to, epoxies, acrylic resins, polyester resins, and the like. The base resin may be a material that has conventionally been used to form solder masks. The use of such a base resin may ensure that the healable dielectric material 22 may be integrated into existing PCB manufacturing processes and that the solder mask 20 formed from the healable dielectric material 22 is compatible with existing manufacturing processes (e.g., assembly, solder reflow, etc.).

In addition to the base resin, the healable dielectric material 22 may include one or more thermoplastic polymers. The one or more thermoplastic polymers may include a polyurethane. Polyurethanes are durable and flexible. The properties of polyurethanes may be tailored by modifying their polyol and isocyanate components. Alternatively or additionally, the one or more thermoplastic polymers may include a polyimide. Polyimides are thermally stable, chemically resistant, and may contribute to the mechanical properties of a solder mask 20 (e.g., a strength, a toughness, a hardness, a ductility, a brittleness, etc., of the solder mask 20).

In addition to hydrogen bonding in the healable dielectric material 22, the HARP(s) 24 (e.g., the DCP(s), DA adduct(s), and/or metal-ligand coordination polymer(s), etc.) of the healable dielectric material 22 may impart the healable dielectric material 22 with further properties (e.g., additional types of bonds, etc.) that enable healing of physical damage to the healable dielectric material 22 and, thus, the healing of damage to a solder mask 20 formed by the healable dielectric material 22.

Hydrogen bonds 26 within the healable dielectric material 22 are non-covalent interactions between molecules with electronegative atoms. Hydrogen bonds 26 in the healable dielectric material 22 can be reversed, or broken, by heating the healable dielectric material 22. Hydrogen bonds 26 can be reestablished by allowing the healable dielectric material 22 to cool.

A DCP includes covalent bonds 27 that can reverse, or break, and reform under specific conditions. For example, the application of heat to the healable dielectric material 22 can break the covalent bonds 27 of a DCP, while covalent bonds 27 of the DCP can form as the healable dielectric material 22 cools.

In a DA adduct, a [4+2] cycloaddition reaction, or a DA reaction, has occurred between a diene and a dienophile, creating two pi (π) bonds and two sigma (σ) bonds 28 between the diene and the dienophile. The π bonds and σ bonds 28 may be broken (i.e., a retro-DA reaction) by heating the healable dielectric material 22. The π bonds and σ bonds 28 may re-form (i.e., DA reaction) by allowing the healable dielectric material 22 to cool.

A metal-ligand coordination polymer includes metal-ligand coordination bonds 29, in which a metal ion (e.g., a zinc ion, or Zn²⁺, etc.) coordinates to one or more ligands. Metal-ligand coordination bonds 29 may be broken by heating the healable dielectric material 22. Metal-ligand coordination bonds 29 may re-form by allowing the healable dielectric material 22 to cool.

Breaking bonds 26, 27, 28, 29 in the healable dielectric material 22 allows at least some components of the healable dielectric material 22 to reflow into damaged areas of the solder mask 20. The temperature at which various bonds 26, 27, 28, 29 in the healable dielectric material 22 may break may be the repair temperature of the healable dielectric material 22. The repair temperature of the healable dielectric material 22 may be about 180° C. or less. In some examples, the repair temperature of the healable dielectric material 22 may be in a range of about 100° C. to about 150° C. or in a range of about 100° C. to about 130° C. In some examples, the repair temperature of the healable dielectric material 22 may be an operating temperature of a PCB 10 the solder mask 20 covers, which may enable any damage to the solder mask 20 to self-heal during operation of an electronic device of which the PCB 10 and solder mask 20 are a part. Once the healable dielectric material 22 has reflowed into damaged areas of the solder mask 20, the healable dielectric material 22 may be allowed to cool. As the healable dielectric material 22 cools, the bonds 26, 27, 28, 29 re-form, re-establishing the integrity of the solder mask 20 formed by the healable dielectric material 22 and completing repair of the solder mask 20.

In addition to the above-described materials, the healable dielectric material 22 may include one or more hardeners. The hardener(s) may react with the resin to define the strength and other properties (e.g., hardness, ductility, brittleness, etc.) of the healable dielectric material 22 and a solder mask 20 formed from the healable dielectric material 22.

The healable dielectric material 22 may also include one or more additives. Some nonlimiting examples of additives include fillers, colorants, ultraviolet (UV) absorbers, and the like. A filler may optimize the mechanical properties, thermal resistance, and chemical resistance of the healable dielectric material 22 and a solder mask 20 formed from the healable dielectric material 22. A colorant may define the color of the healable dielectric material 22 and a solder mask 20 formed from the healable dielectric material 22. A UV absorber may enable the use of UV exposure and chemical development processes to fabricate solder masks 20 or other structures from the healable dielectric material 22.

In a specific but nonlimiting example, the healable dielectric material 22 may be formulated as follows:

| Material | Wt % of Total (±2%) |
|---|---|
| Base Resin | 60% |
| Polyurethane(s) | 8% |
| Polyimide(s) | 6% |
| Dynamic Covalent Polymer(s) (DCP) | 8% |
| Diels-Alder (DA) Adduct(s) | 2% |
| Zinc-Ligand Coordination Bonds | 2% |
| Hydrogen Bonds | — |
| Fillers | 15% |
| Additives | 3% |
| Colorants | 1% |

FIGS. 2-5 illustrate a process for repairing damage 23 to a solder mask 20 formed from a healable dielectric material 22 is illustrated and described.

In FIG. 2, a solder mask 20 may be damaged. Some examples of damage 23 to a solder mask 20 include scratches, microcracks, and cracks. The damage 23 may occur following formation of the solder mask 20 on a PCB 10, during assembly of the PCB 10 and solder mask 20 with other components (e.g., controllers; memory devices, such as NAND devices; etc.), during handling of an assembly that includes the PCB 10 and the solder mask 20 (e.g., during the manufacture of an electronic device, etc.), or during use of an electronic device that includes the PCB 10 and the solder mask 20. In some circumstances, such as during inspection of the solder mask 20 shortly after its manufacture or during inspection of an assembly that includes the PCB 10 and solder mask 20, any damage 23 to the solder mask 20 may be detected. In other circumstances, such as during the manufacture or use of an electronic device that includes the PCB 10 and solder mask 20, any damage 23 to the solder mask 20 may go undetected.

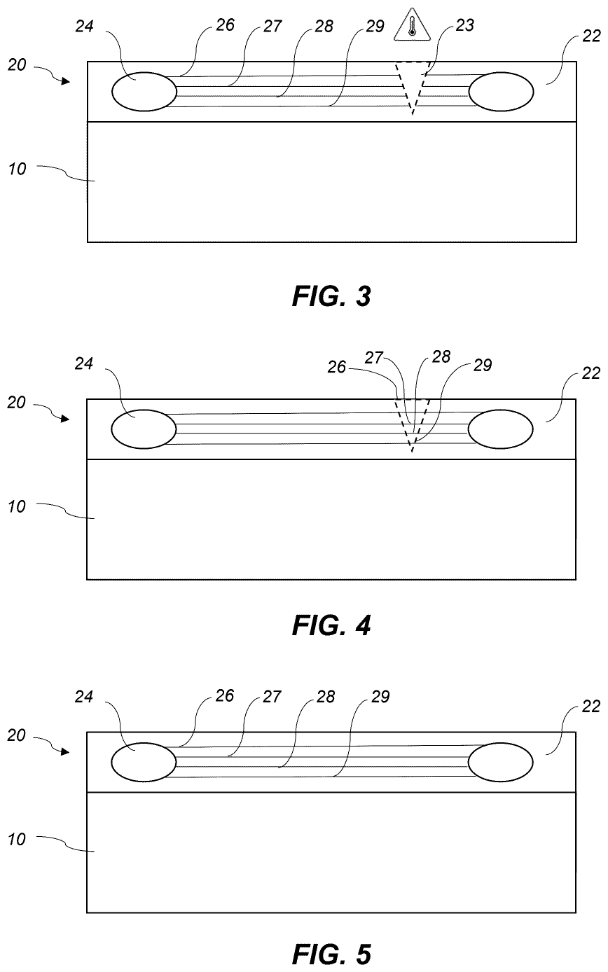

In FIG. 3, heat may be applied to the solder mask 20 to repair any damage 23 to the solder mask 20. The heat may be applied in any suitable manner. For example, heat may be applied by placing the PCB 10 that carries the solder mask 20 into an oven heated to a suitable temperature. The heat may be applied to intentionally repair damage 23 to the solder mask 20. Alternatively, heat applied to the solder mask 20 may automatically and, thus, unintentionally, repair damage 23 to the solder mask 20. For example, heat may be applied to the solder mask 20 as part of subsequent processing of the PCB 10 that carries the solder mask 20; for example, in a reflow oven as solder electrically couples one or more semiconductor devices (e.g., controllers, memory devices, etc.) to the PCB 10. As another example, heat may be applied during operation of an electronic device that includes the PCB 10 that carries the solder mask 20.

The amount of heat applied to the solder mask 20 may be a repair temperature of the healable dielectric material 22 of the solder mask 20. The repair temperature may be about 180° C. or less. In some examples, the repair temperature may be in a range of about 100° C. to about 150° C. or in a range of about 100° C. to about 130° C. In some examples, the repair temperature may be an operating temperature of a PCB 10 the solder mask 20 covers, or the temperature of the PCB 10 during normal operation of an electronic device of which the PCB 10 is a part.

As heat is applied to the solder mask 20, bonds in the healable dielectric material 22 of the solder mask 20 may break. These bonds may include hydrogen bonds 26, covalent bonds 27 of a DCP, π bonds and σ bonds 28 of a DA adduct, and/or metal-ligand coordination bonds 29 of a metal-ligand coordination polymer. As the bonds break, the healable dielectric material 22 may reflow.

The healable dielectric material 22 may reflow into any damage 23 (e.g., scratches, microcracks, cracks, etc.) to the solder mask 20. Once the healable dielectric material 22 reflows into any damage 23, the heat may be removed from the solder mask 20 and the healable dielectric material 22, allowing the healable dielectric material 22 to cool. As shown in FIG. 4, as the healable dielectric material 22 cools, bonds 26, 27, 28, 29 in the healable dielectric material 22 may re-form. These bonds may include hydrogen bonds 26, covalent bonds 27 of a DCP, π bonds and σ bonds 28 of a DA adduct, and/or metal-ligand coordination bonds 29 of a metal-ligand coordination polymer. The re-formation of bonds in the healable dielectric material 22 may reestablish the full structural and chemical integrity of the solder mask 20, as shown in FIG. 5.

The use of a healable dielectric material 22 to form a solder mask 20 may enable damage to the solder mask 20 to be repaired at any time after the solder mask 20 has been manufactured, including prior to assembly of the PCB 10 on which the solder mask 20 is formed with other devices (e.g., semiconductor devices, such as a memory device, a controller, etc.). For example, PCBs 10 that have failed inspection because of solder masks 20 that have been damaged (e.g., scratched, cracked, etc.) may simply be heated (e.g., placed in an oven, etc.) to repair the damage, and then re-inspected. Enabling the salvage of PCBs 10 with damaged solder masks 20 may improve the overall efficiency of the PCB manufacturing process.

A solder mask 20 formed from the healable dielectric material 22 may be repeatedly repaired. In some cases, the solder mask 20 formed from the healable dielectric material 22 may be subjected to the repair temperature multiple times.

The use of a healable dielectric material 22 to form a solder mask 20 on a PCB 10 may also maintain the integrity of the solder mask 20 over time, increasing the durability and longevity of the PCB 10 and increasing the reliability of an electronic device (e.g., an SSD, etc.) into which the PCB 10 has been incorporated. Thus, the use of a solder mask 20 formed from the healable dielectric material 22 in an electronic device may reduce the likelihood that an expensive repair or replacement will be required.

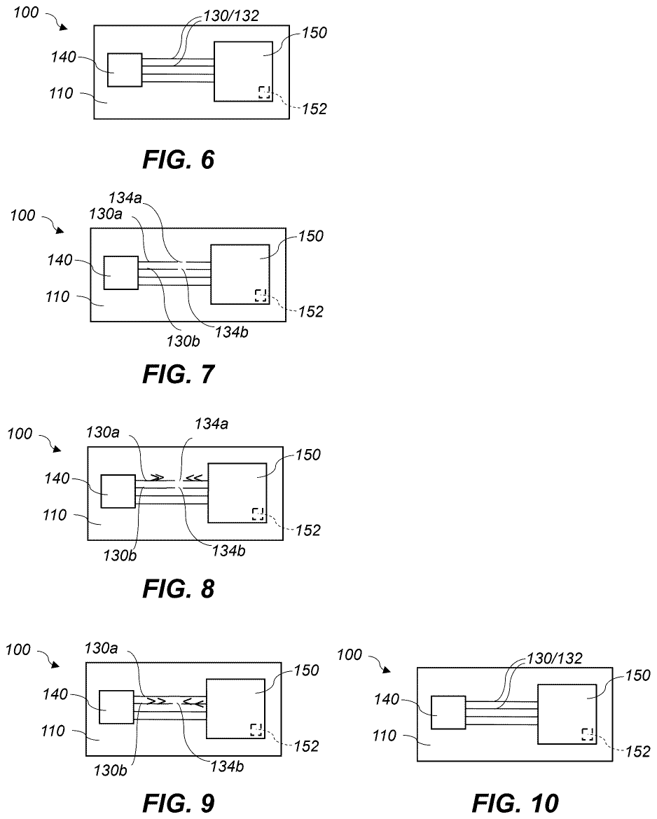

Turning now to FIG. 6, an example of an electronic device assembly 100 is depicted that includes a printed circuit board (PCB) 110 with conductive traces, which may also be referred to as traces 130, formed from a material that may be healed, or a healable conductive material 132. Thus, the traces 130 comprise healable conductive traces. The healable conductive material 132 of the traces 130 may facilitate the repair of damage to the traces 130 (e.g., breaks in the traces 130, etc.).

The healable conductive material 132 may comprise a high-performance plastic with conductive particles dispersed therethrough.

The high-performance plastic of the healable conductive material 132 that can be used to define very fine features, such as the traces 130 of a PCB 110, by processes that are suitable for use in manufacturing PCBs. The inclusion of a high-performance plastic in the healable conductive material 132 may impart traces 130 with greater flexibility than conventional copper traces; the increased flexibility may enable the traces 130 to better withstand physical trauma than conventional copper traces and, thus, may increase the potential lifespan of a PCB 110 that includes traces 130 formed from the healable conductive material 132. In addition, the high-performance plastic of the trace 130 may be highly cross-linked, increasing its stability and enabling the high-performance plastic to withstand the operating conditions (e.g., changes in temperature, relatively high operating temperatures, etc.) to which PCBs are typically subjected better than conventional copper traces. In a specific example, the high-performance plastic of the healable conductive material 132 may comprise polyimide, which can withstand repeated fluctuations in temperature. For example, while conventional PCBs with copper traces may function at operating temperatures of up to about 85° C., a PCB 110 with traces 130 formed from a healable conductive material 132 that includes a polyimide may function at operating temperatures of up to about 120° C.; thus, use of the healable conductive material 132 to define the traces 130 of a PCB 110 may enhance performance of the PCB 110 in demanding environments, relative to the performance of a conventional PCB with copper traces in demanding environments. In some examples, the high-performance plastic (e.g., polyimide, etc.) may account for about 79% to about 90% of the weight of the healable conductive material 132.

The conductive particles of the healable conductive material 132 may comprise particles of silver (Ag) and particles of copper (Cu). The particles may comprise nanoparticles, with sizes (e.g., diameters, etc.) of about 20 nm to about 50 nm. The concentration of conductive particles in the healable conductive material 132 may enable a trace 130 formed from the healable conductive material 132 to reliably conduct electrical signals at a low voltage, such as the operating voltage (e.g., about 3.3 V, about 5 V, etc.) of an electronic device assembly 100 that includes the PCB 110. For example, the healable conductive material 132 may have a resistivity comparable to the resistivity copper, which is about 1.7×10⁻⁸ Ω·m. For example, the healable conductive material 132 may have a resistivity of about 5.0×10⁻⁸ Ω·m or less. In nonlimiting examples, the conductive particles may make up about 10% to about 15% of the weight of the healable conductive material 132.

Optionally, the healable conductive material 132 may include conductive additives, which may further improve the electrical properties of the healable conductive material 132. Conductive additives may enable the healable conductive material 132 to reliably conduct low voltage electrical signals. Conductive additives may contribute to the ability the healable conductive material 132 to heal and, thus, the ability of the healable conductive material 132 to repair a break in a trace 130. Without limitation, carbon nanotubes and/or graphene may be included in the healable conductive material 132. In more specific examples, the healable conductive material 132 may include both carbon nanotubes and graphene. Even more specifically, each of the carbon nanotubes and the graphene may make up about 2% to about 3% of the weight of the healable conductive material 132.

Such a healable conductive material 132 may be used to form traces 130 with widths of about 500 μm to about 1,000 μm and thicknesses of about 20 μm to about 50 μm, as compared with the traces of conventional PCBs, which are typically about 1,000 μm wide and about 35 μm thick.

In addition to enabling the design of traces 130 that are potentially thinner than the copper traces of conventional PCBs, the use of a healable conductive material 132 may enable the use of insulative layers that are thinner than the insulative layers of conventional PCBs. For example, while a conventional PCB with copper traces may have insulative layers that are as thin as about 50 μm, a PCB 110 with traces 130 formed from the healable conductive material 132 may be as thin as about 30 μm. Moreover, testing has shown that traces 130 formed from the healable conductive material 132 fail at a rate of only about 1%, as opposed to the 10% failure rate of conventional copper traces, indicating that a PCB 110 with traces 130 formed from the healable conductive material 132 are much more reliable (e.g., up to about 10 times more reliable) than conventional PCBs with copper traces. Thus, using the healable conductive material 132 to form the traces 130 may enable the design and manufacture of PCBs 110 that are significantly thinner and substantially more reliable than conventional PCBs with copper traces.

It has been discovered that such a healable conductive material 132 may flow over short distances when exposed to an electrical field with voltages that exceed the typical operating voltages of electronic devices. For example, the healable conductive material 132 may flow when exposed to a voltage of greater than 5 V. As a more specific example, the healable conductive material 132 may flow when a voltage of more than 5V to about 10V is applied to it. Subjecting the healable conductive material 132 to such a voltage may heat the healable conductive material 132 (e.g., to a temperature of about 120° C., etc., higher than normal operating temperatures of about 60° C. to about 85° C.), which may cause the healable conductive material 132 to flow. The voltage that causes the healable conductive material 132 to flow may be referred to as a “repair voltage.”

The application of a repair voltage to a trace 130 formed from the healable conductive material 132 may cause the healable conductive material 132 to flow over a break 134 (FIG. 7) as large as about 10 μm in the trace 130. As the healable conductive material 132 flows, it may bridge the break 134 and, thus, restore functionality to the trace 130.

Traces 130 formed from the healable conductive material 132 may be repeatedly repaired. In some cases, a trace 130 formed from the healable conductive material 132 may be subjected to the repair voltage multiple times.

With continued reference to FIG. 6, the electronic device assembly 100 may additionally include a first semiconductor device 140 and a second semiconductor device 150 on the PCB 110. The traces 130 may establish electrically conductive links between the first semiconductor device 140 and the second semiconductor device 150 and, thus, enable the first semiconductor device 140 and second semiconductor device 150 to communicate with each other.

In examples where the electronic device assembly 100 comprises an SSD, the first semiconductor device 140 may comprise a controller. Such a first semiconductor device 140 may be programmed to control operation of the electronic device assembly 100 and enable the electronic device assembly 100 to communicate with other electronic devices. Such a first semiconductor device 140 may also be to identify any broken or otherwise damaged traces 130 of the PCB 110; for example, the first semiconductor device 140 may include circuits that are dedicated and programmed to monitor for problems. In addition, such a first semiconductor device 140 may be programmed to apply a repair voltage to one or more broken or otherwise damaged traces 130. In some examples, while the first semiconductor device 140 applies a repair voltage to a broken or otherwise damaged trace 130 on one side of a break 134 or other damage, the first semiconductor device 140 may be further programmed to cause the second semiconductor device 150 to apply the repair voltage to the broken or otherwise damaged trace 130 from the other side of the break 134 or other damage.

The second semiconductor device 150 of an electronic device assembly 100 that comprises an SSD may be a memory device, such as a NAND device. In examples where the second semiconductor device 150 can apply a repair voltage to a broken or otherwise damaged trace 130, the second semiconductor device 150 may include a multiplier circuit 152. The multiplier circuit may increase, or step up, the relatively low operating voltage (e.g., about 3.3 V or about 5 V) to a higher repair voltage (e.g., a voltage in a range of above 5 V. to about 10 V, etc.).

During normal operation, the electronic device assembly 100 (e.g., an SSD, etc.) functions as expected, with electrical signals flowing through the traces 130 of the PCB 110. The first semiconductor device 140 (e.g., a controller, etc.) may monitor performance of the electronic device assembly 100, including the PCB 110 and its traces 130, ensuring the electronic device assembly 100 functions optimally (e.g., with optimal read/write speeds and data integrity of the second semiconductor device 150-a memory device, without any interruptions, etc.).

While the first semiconductor device 140 continues to monitor performance of the electronic device assembly 100, it may detect a break 134 or other damage to one or more conductive traces 130 of the PCB 110, as shown in FIG. 7. Programming of the first semiconductor device 140, or dedicated monitoring circuits of the first semiconductor device 140, may enable the first semiconductor device 140 to identify a trace 130 with a break 134 or other damage. In FIG. 7, two traces 130, which FIG. 7 identifies as trace 130a and trace 130b, have been broken.

As depicted by FIG. 8, once a break 134 or other damage to a trace 130a has been detected, the first semiconductor device 140 may apply a repair voltage 145 to the trace 130a at one side of the break 134a or other damage. Optionally, the first semiconductor device 140 may cause the second semiconductor device 150, or a multiplier circuit 152 of the second semiconductor device 150 to apply the repair voltage to the trace 130a at an opposite side of the break 134a or other damage. Application of the repair voltage to the trace 130a from opposite sides of the break 134a or other damage may ensure that the healable conductive material 132 flows into the break 134a or other damage along the original path of the trace 130a rather than toward other traces 130a or conductive features of the PCB 110. Optionally, the PCB 110 may include an additional insulator adjacent to the sides and/or bottom of each trace 130 to prevent the healable conductive material 132 of the trace 130 from flowing beyond the trace 130's original pathway and potentially creating electrical issues (e.g., shorts, etc.) between a repaired trace 130 and other electrical features (e.g., other traces 130, etc.) of the PCB 110.

The first semiconductor device 140 may monitor the conductivity of the trace 130a as the break 134a or other damage to the trace 130 is repaired. Once the ability of the trace 130a to conduct electrical signals is restored, the first semiconductor device 140 may terminate the repair process. Additionally, if the repair process has continued for a predetermined duration of time without restoring the ability of the trace 130a to conduct electrical signals, the first semiconductor device 140 may terminate the repair process and provide an output indicating that the trace 130a has been irreparably damaged.

FIG. 9 depicts the repair of a break 134b in another trace 130b of the PCB 110 in the same manner as that described in reference to FIG. 8. Repair of the trace 130b may occur at least partially concurrently with the repair of trace 130a or after the repair of trace 130a is complete. The localized electric fields generated by applying the repair voltage across each break may prevent cross-connections from forming between adjacent breaks 134a and 134b.

FIG. 10 shows the electronic device assembly 100 including repaired traces 130a and 130b. Once a break 134 or other damage to a trace 130 of the PCB 110 has been repaired, normal operation of the electronic device assembly 100 may resume.

Some examples of a PCB may include at least one solder mask 20 formed from a healable dielectric material 22, such as those described in reference to FIG. 1, and traces 130 formed from a healable conductive material 132 of the type described in reference to FIG. 6. Similarly, some examples of electronic device assemblies, such as the electronic device assembly 100 described in reference to FIG. 6, may include a PCB 10, 110 with at least one solder mask 20 formed from a healable dielectric material 22, as described in reference to FIG. 1, and traces 130 formed from a healable conductive material 132, as described in reference to FIG. 6.

Based on the above, examples of the present disclosure describe a printed circuit board (PCB), comprising at least one of: a solder mask comprising a healable dielectric material that flows at a repair temperature at or above an operating temperature of an electronic device into which the PCB is to be incorporated; and traces defined from a healable conductive material that flows upon application of a repair voltage to a trace of the traces, the repair voltage exceeding an operating voltage of the electronic device into which the PCB is to be incorporated. In an example, the solder mask includes a base resin, at least one thermoplastic resin, and at least one heat-activated reversible polymer (HARP). In an example, the at least one HARP includes a dynamic covalent polymer (DCP), a Diels-Alder (DA) adduct, and/or a metal-ligand coordination polymer. In an example, the repair temperature is in a range from 100° C. to 130° C. In an example, the healable conductive material comprises a polyimide having silver nanoparticles and copper nanoparticles dispersed throughout the polyimide. In an example, at least one of the silver nanoparticles and the copper nanoparticles have sizes in a range between 20 (nanometers) nm and 50 nm. In an example, the polyimide further comprises at least one of carbon nanotubes and graphene. In an example, the repair voltage is in a range between 5 volts (V) and 10 V. In an example, the PCB carries a controller and a memory device, the controller programmed to monitor performance of the PCB, detect a break to the trace, and apply the repair voltage to the trace from a first side of the break. In an example, the memory device includes a multiplier circuit; and the controller is further programmed to cause the multiplier circuit of the memory device to apply the repair voltage to the trace on a second side of the break, opposite from the first side of the break.

Examples also describe a method for repairing a break in a trace of a printed circuit board (PCB), comprising: identifying the trace with the break; and applying a repair voltage to the trace to repair the break, the repair voltage exceeding an operating voltage of an electronic device in which the PCB is provided. In an example, applying the repair voltage comprises applying a voltage in a range between 5 V and 10 V to the break. In an example, applying the repair voltage comprises applying the repair voltage to the trace from opposite sides of the break. In an example, applying the repair voltage from opposite sides of the break comprises: applying the repair voltage from a first side of the break with a processor that communicates with trace; and applying the repair voltage from a second side of the break. In an example, applying the repair voltage from the second side of the break comprises applying the repair voltage from a multiplier circuit associated with the electronic device.

Examples also describe a method for repairing damage to a solder mask on a printed circuit board (PCB), comprising: detecting damage to the solder mask; applying heat to the damage, including: breaking Diels-Alder bonds in a material of the solder mask; breaking hydrogen bonds in the material of the solder mask; and disassociating metal-ligand bonds in the material of the solder mask; and allowing the material of the solder mask to cool, including: reestablishing Diels-Alder bonds in the material of the solder mask; reestablishing hydrogen bonds in the material of the solder mask; and reassociating metal-ligand bonds in the material of the solder mask. In an example, applying heat to the damage comprises applying heat to an entirety of the solder mask. In an example, applying heat comprises exposing the solder mask to a temperature in range between 100° C. and 130° C. In an example, the PCB is included in a data storage device. In an example, applying heat occurs during operation of the data storage device.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an example with a particular set of features. Having been provided with the description and illustration of the present disclosure, one skilled in the art may envision variations, modifications, and alternate aspects falling within the spirit of the broader aspects of the general inventive concept embodied in this disclosure that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed:

1. A printed circuit board (PCB), comprising at least one of:
a solder mask comprising a healable dielectric material that flows at a repair temperature at or above an operating temperature of an electronic device into which the PCB is to be incorporated; and
traces defined from a healable conductive material that flows upon application of a repair voltage to a trace of the traces, the repair voltage exceeding an operating voltage of the electronic device into which the PCB is to be incorporated.

2. The PCB of claim 1, wherein the solder mask includes a base resin, at least one thermoplastic resin, and at least one heat-activated reversible polymer (HARP).

3. The PCB of claim 2, wherein the at least one HARP includes a dynamic covalent polymer (DCP), a Diels-Alder (DA) adduct, and/or a metal-ligand coordination polymer.

4. The PCB of claim 1, wherein the repair temperature is in a range from 100° C. to 130° C.

5. The PCB of claim 1, wherein the healable conductive material comprises a polyimide having silver nanoparticles and copper nanoparticles dispersed throughout the polyimide.

6. The PCB of claim 5, wherein at least one of the silver nanoparticles and the copper nanoparticles have sizes in a range between 20 (nanometers) nm and 50 nm.

7. The PCB of claim 5, wherein the polyimide further comprises at least one of carbon nanotubes and graphene.

8. The PCB of claim 5, wherein the repair voltage is in a range between 5 volts (V) and 10 V.

9. The PCB of claim 1, carrying a controller and a memory device, the controller programmed to monitor performance of the PCB, detect a break to the trace, and apply the repair voltage to the trace from a first side of the break.

10. The PCB of claim 9, wherein:
the memory device includes a multiplier circuit; and
the controller is further programmed to cause the multiplier circuit of the memory device to apply the repair voltage to the trace on a second side of the break, opposite from the first side of the break.

11. A method for repairing a break in a trace of a printed circuit board (PCB), comprising:
identifying the trace with the break; and
applying a repair voltage to the trace to repair the break, the repair voltage exceeding an operating voltage of an electronic device in which the PCB is provided.

12. The method of claim 11, wherein applying the repair voltage comprises applying a voltage in a range between 5 V and 10 V to the break.

13. The method of claim 11, wherein applying the repair voltage comprises applying the repair voltage to the trace from opposite sides of the break.

14. The method of claim 13, wherein applying the repair voltage from opposite sides of the break comprises:
applying the repair voltage from a first side of the break with a processor that communicates with trace; and
applying the repair voltage from a second side of the break.

15. The method of claim 14, wherein applying the repair voltage from the second side of the break comprises applying the repair voltage from a multiplier circuit associated with the electronic device.

16. A method for repairing damage to a solder mask on a printed circuit board (PCB), comprising:
detecting damage to the solder mask;
applying heat to the damage, including:
breaking Diels-Alder bonds in a material of the solder mask;
breaking hydrogen bonds in the material of the solder mask; and
disassociating metal-ligand bonds in the material of the solder mask; and
allowing the material of the solder mask to cool, including:
reestablishing Diels-Alder bonds in the material of the solder mask;
reestablishing hydrogen bonds in the material of the solder mask; and
reassociating metal-ligand bonds in the material of the solder mask.

17. The method of claim 16, wherein applying heat to the damage comprises applying heat to an entirety of the solder mask.

18. The method of claim 16, wherein applying heat comprises exposing the solder mask to a temperature in range between 100° C. and 130° C.

19. The method of claim 16, wherein the PCB is included in a data storage device.

20. The method of claim 19, wherein applying heat occurs during operation of the data storage device.
